(19) United States
(12) Patent Application Publication
(10) Pub. No.: US 2026/0135340 A1
(43) Pub. Date: May 14, 2026

(54) BUSBAR ASSEMBLY AND ELECTRICAL CONNECTION ASSEMBLY

(71) Applicant: Tyco Electronics (Shanghai) Co., Ltd., Shanghai (CN)

(72) Inventors: Rong (Summer) Zhang, Shenzhen (CN); Jie (Roger) Luo, Foshan (CN); Jiaoyong (Mac) Liu, Shanghai (CN); William (Wei) Yao, Kunshan (CN)

(73) Assignee: Tyco Electronics (Shanghai) Co., Ltd., Shanghai (CN)

(21) Appl. No.: 19/385,555

(22) Filed: Nov. 11, 2025

(30) Foreign Application Priority Data
Nov. 11, 2024 (CN) 202411605128.0

(51) Int. Cl. H01R 25/16; H05K 7/20

(52) U.S. Cl. CPC H01R 25/162; H05K 7/20254; H05K 7/20272

(57) ABSTRACT

A busbar assembly includes a busbar and a liquid cooling tube. The busbar has a busbar body, a groove formed on the busbar body and extending along a length direction of the busbar body, and a flexible bent part. The flexible bent part is connected to an end of the busbar body and is adapted to permit the busbar to undergo elastic deformation in the length direction. The liquid cooling tube is arranged in the groove of the busbar body and is adapted to cool the busbar.

### CROSS-REFERENCE TO RELATED APPLICATION

This application claims the benefit of Chinese Patent Application No. CN202411605128.0 filed on Nov. 11, 2024, in the State Intellectual Property Office of China, the whole disclosure of which is incorporated herein by reference.

### FIELD OF THE INVENTION

The disclosure relates to a busbar assembly and an electrical connection assembly comprising the busbar assembly.

### BACKGROUND OF THE INVENTION

In the prior art, in order to electrically connect the busbars in two cabinets, a horizontal busbar connection assembly needs to be provided. The existing busbar connection assembly usually includes a positive busbar and a negative busbar. The two ends of the positive busbar are electrically connected to the positive busbars in two cabinets, and the two ends of the negative busbar are electrically connected to the negative busbars in two cabinets. However, the existing busbars are rigid and cannot absorb significant installation and manufacturing errors, such as errors of +/−10 mm. In addition, the existing busbars are large in size in order to carry currents of over 3000 A, resulting in a large cross-sectional area of the busbar body, which makes assembly and maintenance difficult and costly.

### SUMMARY OF THE INVENTION

According to an embodiment of the present disclosure, a busbar assembly includes a busbar and a liquid cooling tube. The busbar has a busbar body, a groove formed on the busbar body and extending along a length direction of the busbar body, and a flexible bent part. The flexible bent part is connected to an end of the busbar body and is adapted to permit the busbar to undergo elastic deformation in the length direction. The liquid cooling tube is arranged in the groove of the busbar body and is adapted to cool the busbar.

### BRIEF DESCRIPTION OF DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 shows an illustrative perspective view of an electrical connection assembly according to an exemplary embodiment of the present invention;

FIG. 2 shows a transverse sectional view of an electrical connection assembly according to an exemplary embodiment of the present invention;

FIG. 3 shows an illustrative perspective view of the flexible bent part of the busbar of an electrical connection assembly according to an exemplary embodiment of the present invention;

FIG. 4 shows an illustrative perspective view of an electrical connection assembly according to an exemplary embodiment of the present invention, with the fixed cover removed;

FIG. 5 shows an illustrative perspective view of an electrical connection assembly according to an exemplary embodiment of the present invention, with the installation shell and fixed cover removed;

FIG. 6 shows an illustrative perspective view of a liquid cooling device for an electrical connection assembly according to an exemplary embodiment of the present invention;

FIG. 7 shows an illustrative perspective view of the busbar assembly of an electrical connection assembly according to an exemplary embodiment of the present invention;

FIG. 8 shows a transverse cross-sectional view of the busbar assembly of an electrical connection assembly according to an exemplary embodiment of the present invention; and

FIG. 9 shows an illustrative perspective view of the busbar of an electrical connection assembly according to an exemplary embodiment of the present invention.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a busbar assembly comprises: a busbar comprising a busbar body and a groove formed on the busbar body and extending along the length direction of the busbar body; and a liquid cooling tube which is accommodated in the groove of the busbar body for cooling the busbar. The busbar also has a flexible bent part connected to the end of the busbar body, allowing the busbar to undergo elastic deformation in the length direction.

According to another embodiment, there is provided an electrical connection assembly. The electrical connection assembly comprises: two above busbar assemblies, with their busbar bodies stacked vertically together; and an insulation isolation plate which is clamped between the busbar bodies of the two busbar assemblies. The busbar body has first and second sides opposite in its thickness direction, the first side of the busbar body is attached to the insulation isolation plate, and the liquid cooling tube is located on the second side of the busbar body.

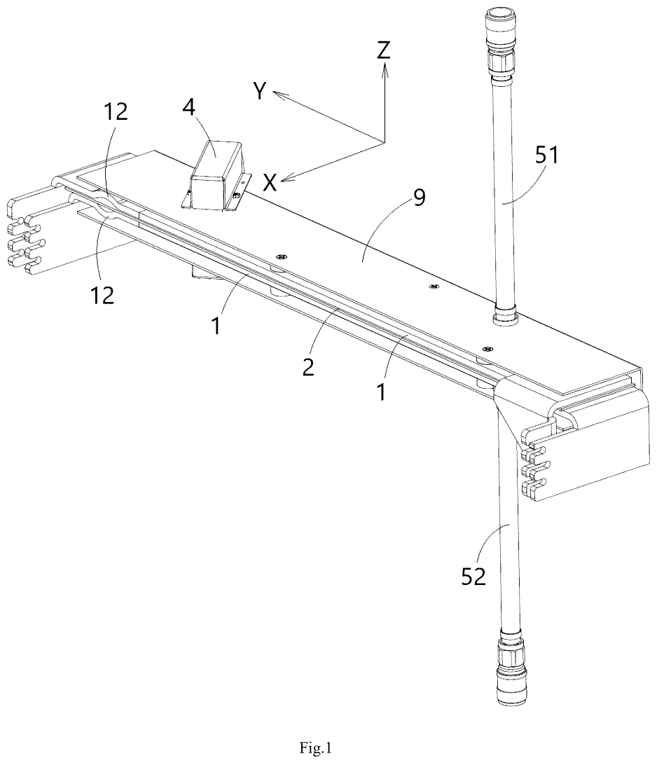

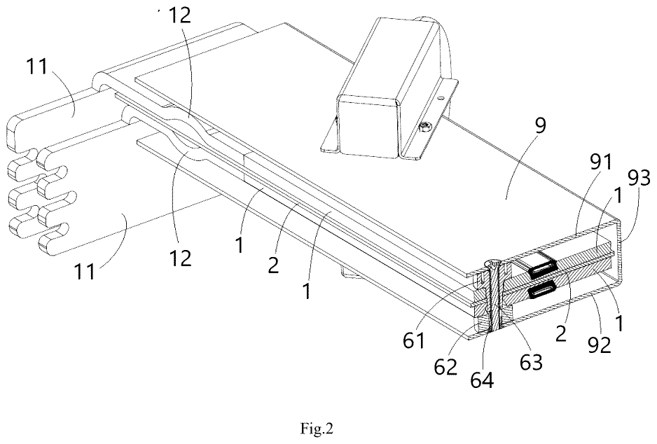

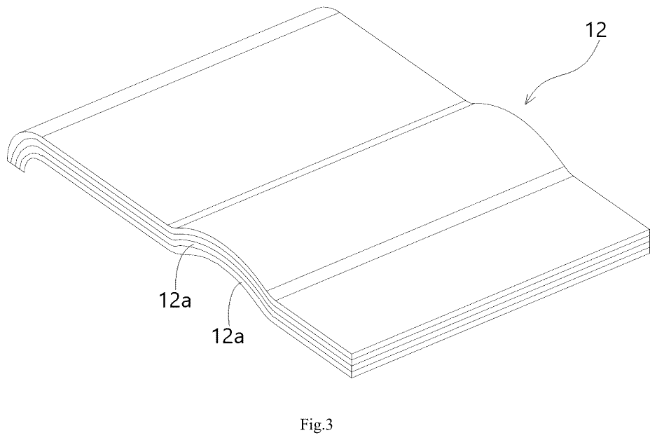

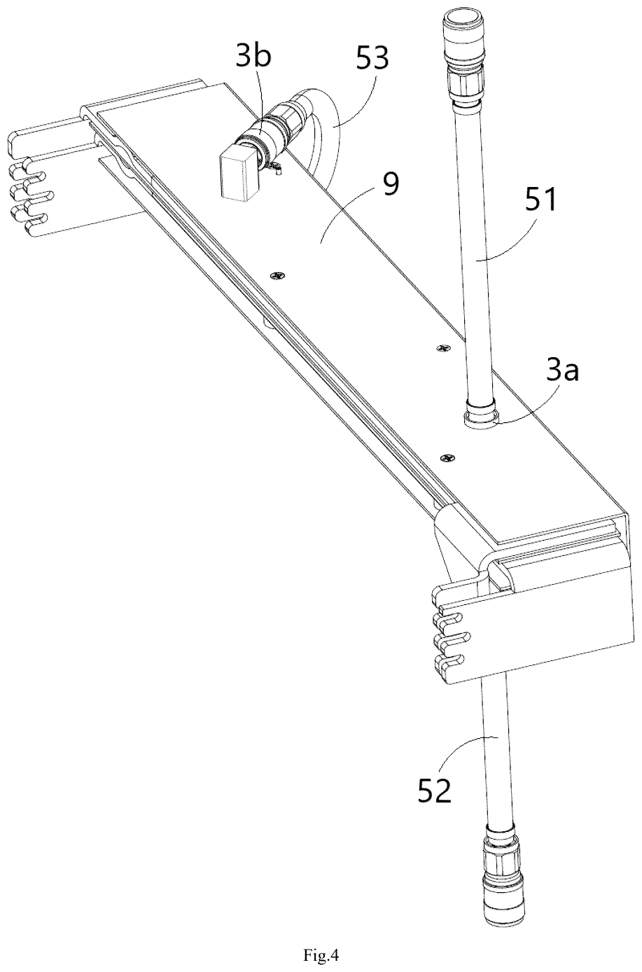

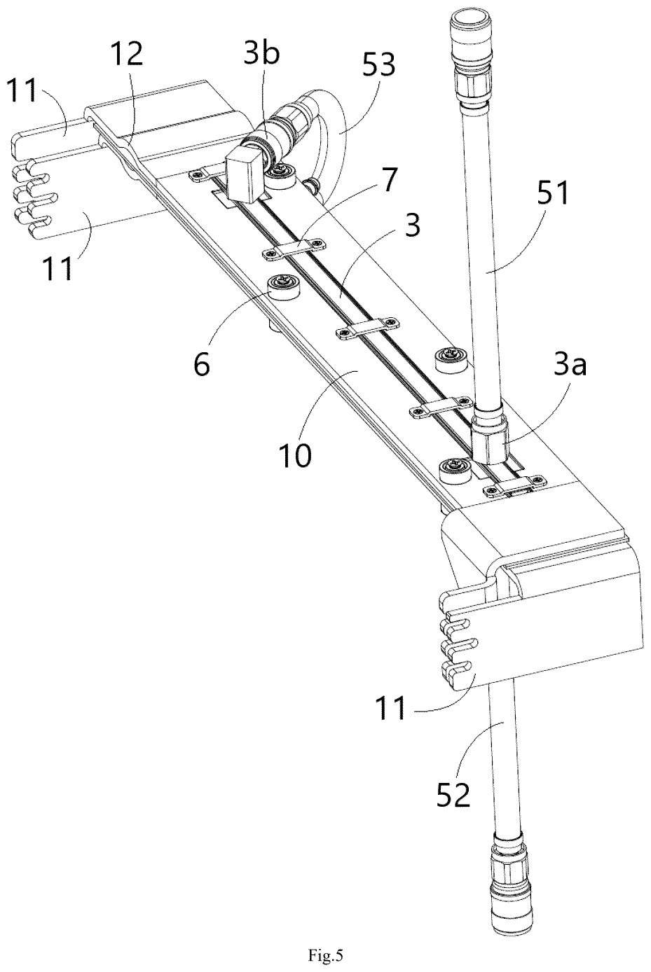

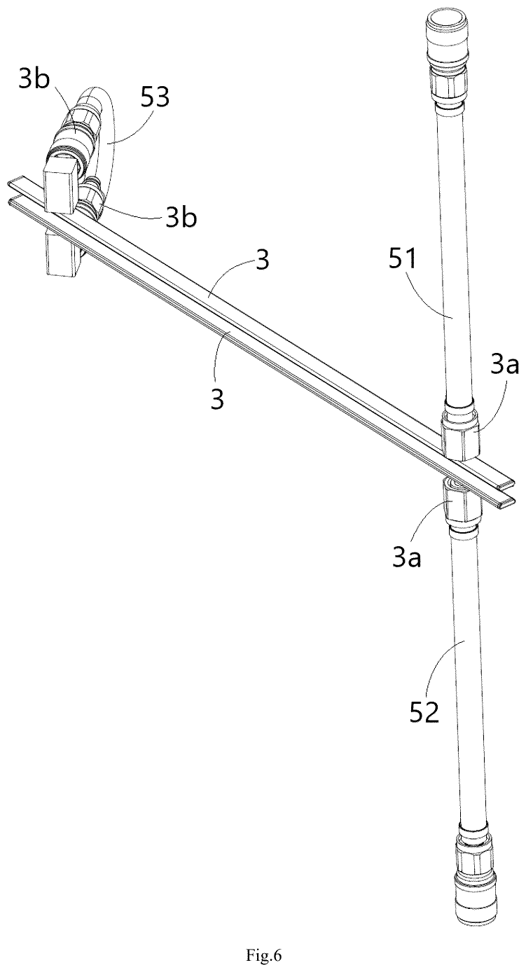

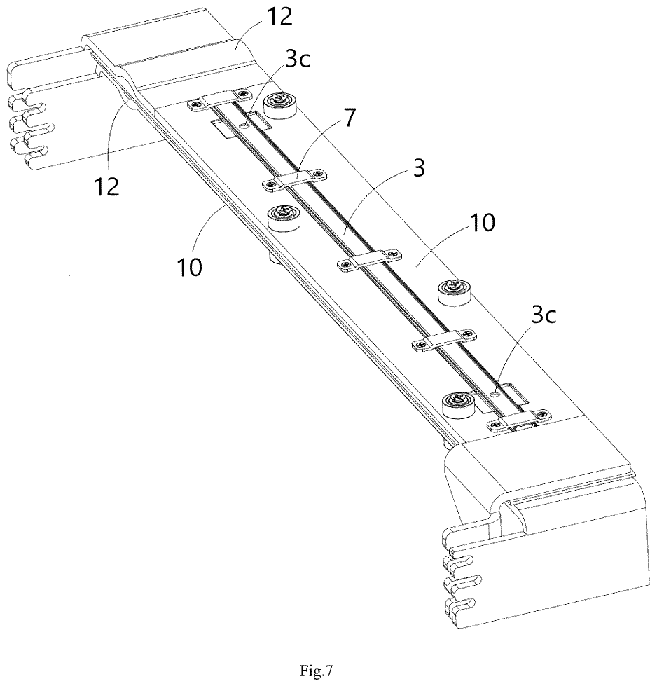

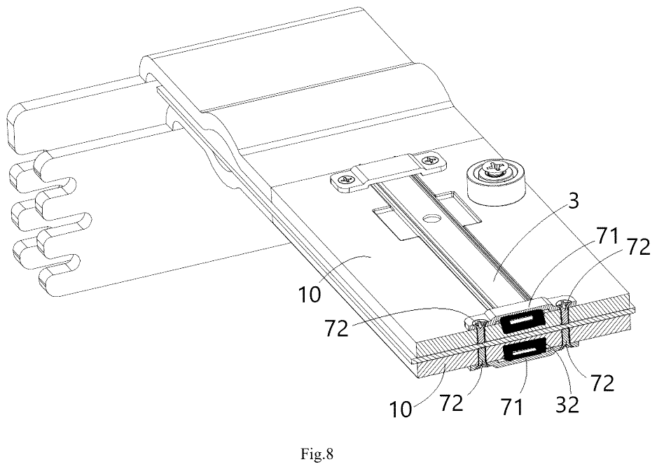

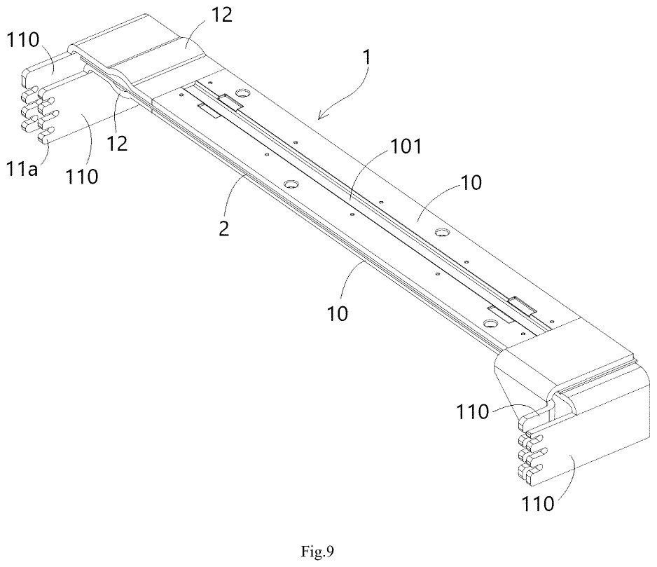

FIG. 1 shows an illustrative perspective view of an electrical connection assembly according to an exemplary embodiment of the present invention. FIG. 2 shows a transverse sectional view of an electrical connection assembly according to an exemplary embodiment of the present invention. FIG. 3 shows an illustrative perspective view of the flexible bent part 12 of the busbar 1 of the electrical connection assembly according to an exemplary embodiment of the present invention. FIG. 4 shows an illustrative perspective view of an electrical connection assembly according to an exemplary embodiment of the present invention, with the fixed cover 4 removed. FIG. 5 shows an illustrative perspective view of an electrical connection assembly according to an exemplary embodiment of the present invention, in which the installation shell 9 and the fixing cover 4 are removed. FIG. 6 shows an illustrative perspective view of a liquid cooling device for an electrical connection assembly according to an exemplary embodiment of the present invention. FIG. 7 shows an illustrative perspective view of the busbar assembly of an electrical connection assembly according to an exemplary embodiment of the present invention. FIG. 8 shows a transverse cross-sectional view of the busbar assembly of an electrical connection assembly according to an exemplary embodiment of the present invention. FIG. 9 shows an illustrative perspective view of busbar 1 of an electrical connection assembly according to an exemplary embodiment of the present invention.

As shown in FIGS. 1-9, in an exemplary embodiment of the present invention, a busbar assembly is disclosed. The busbar assembly includes a busbar 1 and a liquid cooling tube 3. The busbar 1 has a busbar body 10 and a groove 101 formed on the busbar body 10 and extending along the length direction Y of the busbar body 10. The liquid cooling tube 3 is accommodated in the groove 101 of the busbar body 10 for cooling the busbar 1. The busbar 1 also has a flexible bent part 12 connected to the end of the busbar body 1, allowing the busbar 1 to undergo elastic deformation in the length direction Y.

The busbar body 10 is a single flat conductor, and the flexible bent part 12 includes multiple bent flexible sheets 12a stacked together. The flexible bent part 12 is riveted, welded, or bolted to the end of the busbar body 1 for electrical connection with the busbar body 1. In the illustrated embodiment, the flexible sheet 12a is bent into an arc or wave shape. The busbar 1 has a single flexible bent part 12, which is connected to one end of the busbar body 1. However, the present invention is not limited to the illustrated embodiment. For example, in another exemplary embodiment of the present invention, the busbar 1 may have two flexible bent parts 12, which are respectively connected to both ends of the busbar body 1.

As shown in FIGS. 1-9, in the illustrated embodiment, the busbar body 10 has two opposite sides in its thickness direction Z, and the groove 101 is formed on one side of the busbar body 10. The busbar assembly further includes an insulation thermal pad 32, which is disposed between the liquid cooling tube 3 and the busbar body 10, for transferring the heat of the busbar body 10 to the liquid cooling tube 3 and electrically isolating the busbar body 10 from the liquid cooling tube 3.

However, the present invention is not limited to the illustrated embodiments. For example, in another exemplary embodiment of the present invention, the liquid cooling tube 3 may be in direct thermal contact with the busbar body 10 or bonded to the busbar body 10 through a thermal conductive adhesive provided between the liquid cooling tube 3 and the busbar body 10.

The busbar assembly further includes multiple pressing devices 7. The pressing devices 7 are installed on the busbar body 10 to press the liquid cooling tube 3 into the groove 101 of the busbar body 10. This ensures reliable thermal contact between the liquid cooling tube 3 and the insulation thermal pad 32 and ensures reliable thermal contact between the busbar body 10 and the insulation thermal pad 32.

In the illustrated embodiment, multiple pressing devices 7 are arranged in a row along the length direction Y of the busbar body 10. The pressing device 7 includes an insulation pressing plate 71 that spans across the liquid cooling tube 3; The two ends of the insulation pressing plate 71 are tightened to the busbar body 10 with two screws 72, and a predetermined pressing force is applied on the top of the liquid cooling tube 3 with the insulation pressing plate 71. In the illustrated embodiment, the liquid cooling tube 3 is flat and its two ends are closed.

An opening 3c is formed on the top surface of each end of the liquid cooling tube 3 to allow the coolant to flow through. The busbar assembly further includes a first pipe joint 3a and a second pipe joint 3b. The first pipe joint 3a is connected to the opening 3c at one end of the liquid cooling pipe 3. The second pipe joint 3b is connected to the opening 3c at the other end of the liquid cooling pipe 3.

The busbar 1 has a single flexible bent part 12, and one end of the single flexible bent part 12 is connected to one end of the busbar body 1. The busbar 1 also has two connection end portions 11 for electrically connecting to two connection busbars (not shown), one of which is connected to the other end of the flexible bent part 12, and the other is connected to the other end of the busbar body 1.

In another exemplary embodiment of the present disclosure, an electrical connection assembly is also disclosed. The electrical connection assembly includes two busbar assemblies and an insulation isolation plate 2. The busbar bodies 10 of two busbar assemblies is stacked up and down together. The insulation isolation plate 2 is clamped between the busbar bodies 10 of two busbar assemblies. The busbar body 10 has a first side and a second side that are opposite in its thickness direction Z. The first side of the busbar body 10 is attached to the insulation isolation plate 2, and the liquid cooling tube 3 is located on the second side of the busbar body 10.

The electrical connection assembly further comprises an installation shell 9, which has a top plate 91 and a bottom plate 92 opposite in the thickness direction Z of the busbar body 10, and a front opening and a rear side plate 93 opposite in the width direction X of the busbar body 10. The two busbar bodies 10 and the insulation isolation plate 2 are fixedly installed in the installation shell 9.

In the illustrated embodiment, the electrical connection assembly further includes a fastening assembly 6, which fastens the two busbar bodies 10 and the insulation isolation plate 2 to the top plate 91 and bottom plate 92 of the installation shell 9. The electrical connection assembly includes multiple fastening assemblies 6, which are spaced apart in the length direction Y of the busbar body 10, and adjacent two fastening assemblies 6 are located on both sides of the groove 101.

The fastening assembly 6 includes a first insulation component 61, a second insulation component 62, a nut 64, and a bolt 63. The first insulation component 61 includes an end part 611 clamped between the top plate 91 of the installation shell 9 and one busbar body 10, and a cylindrical part 612 passing through two busbar bodies 10 and the insulation isolation plate 2. The second insulation component 62 is clamped between the bottom plate 92 of the installation shell 9 and the other busbar body 10. The nut 64 is fixed to the top plate 91 or bottom plate 92 of the installation shell 9. The bolt 63 passes through the top plate 91 and bottom plate 92 of the installation shell 9, as well as the cylindrical part 612 of the first insulation component 61. The bolt 63 is threaded with nut 64, and the cylindrical part 612 of the first insulation component 61 electrically isolates the bolt 63 from the two busbar bodies 10.

The first pipe joint 3a and the second pipe joint 3b of one busbar assembly pass through the top plate 91 of the installation shell 9 and are fixed to the top plate 91 of the installation shell 9. The first pipe joint 3a and the second pipe joint 3b of the other busbar assembly pass through the bottom plate 92 of the installation shell 9 and are fixed to the bottom plate 92 of the installation shell 9.

The electrical connection assembly further includes an inlet pipe 51, an outlet pipe 52, and a connecting pipe 53. The inlet pipe 51 is connected to the first pipe joint 3a of one busbar assembly. The outlet pipe 52 is connected to the first pipe joint 3a of the other busbar assembly. The two ends of the connecting pipe 53 are respectively connected to the second pipe joints 3b of the two busbar assemblies, used to interconnect the liquid cooling pipes 3 of the two busbar assemblies. The electrical connection assembly further includes two fixed covers 4, which are respectively fixed to the top plate 91 and the bottom plate 92 of the installation shell 9. The first pipe joints 3a of the two busbar assemblies are respectively accommodated and fixed in two fixed covers 4.

In the illustrated embodiment, the two connection end portions 11 of one busbar 1 of the electrical connection assembly are used to electrically connect to two positive connection busbars (not shown) respectively, and the two connection end portions 11 of the other busbar 1 of the electrical connection assembly are used to electrically connect to two negative connection busbars (not shown) respectively.

The connection end portion 11 of the busbar 1 has a vertical connecting plate 110 perpendicular to the length direction Y of the busbar body 10, and the vertical connecting plate 110 has a row of teeth 11a suitable for insertion into a row of sockets formed in the connection busbar. The vertical connecting plates 110 at one end of the two busbars 1 are spaced apart in the length direction Y of the busbar body 10, and the vertical connecting plates 110 at the other end of the two busbars 1 are spaced apart in the length direction Y of the busbar body 10.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A busbar assembly, comprising:
a busbar including:
a busbar body;
a groove formed on the busbar body and extending along a length direction of the busbar body; and
a flexible bent part connected to an end of the busbar body and adapted to permit the busbar to undergo elastic deformation in the length direction; and
a liquid cooling tube arranged in the groove of the busbar body and adapted to cool the busbar.

2. The busbar assembly according to claim 1, wherein the busbar body is a single flat conductor, and the flexible bent part comprises multiple bent flexible sheets stacked together.

3. The busbar assembly according to claim 2, wherein the flexible bent part is riveted or welded to the end of the busbar body for electrical connection with the busbar body.

4. The busbar assembly according to claim 2, wherein the flexible sheet is bent into an arc shape or a wave shape.

5. The busbar assembly according to claim 1, wherein the busbar has two flexible bent parts respectively connected to the two ends of the busbar body.

6. The busbar assembly according to claim 1, wherein the busbar has a single flexible bent part connected to one end of the busbar body.

7. The busbar assembly according to claim 1, wherein the busbar body has two opposite sides in a thickness direction, and the groove is formed on one side of the busbar body.

8. The busbar assembly according to claim 1, further comprising an insulation thermal pad arranged between the liquid cooling tube and the busbar body, and adapted to transfer heat from the busbar body to the liquid cooling tube and electrically isolate the busbar body from the liquid cooling tube.

9. The busbar assembly according to claim 1, wherein the liquid cooling tube is in direct thermal contact with the busbar body or bonded to the busbar body through a thermal conductive adhesive set between the liquid cooling tube and the busbar body.

10. The busbar assembly according to claim 8, further comprising multiple pressing devices arranged on the busbar body and adapted to press the liquid cooling tube into the groove of the busbar body.

11. The busbar assembly according to claim 10, wherein:
the multiple pressing devices are arranged in a row along the length direction of the busbar body; and
the pressing device includes:
an insulation pressing plate extending across the liquid cooling pipe; and
a pair of screws fastening two ends of the insulation pressing plate to the busbar body, respectively, the insulation pressing plate applying a predetermined pressing force on the top of the liquid cooling tube.

12. The busbar assembly according to claim 1, wherein the liquid cooling tube is flat and includes closed ends, an opening is formed on a top surface of each end of the liquid cooling tube to allow the coolant to flow through.

13. The busbar assembly according to claim 12, further comprising:
a first pipe joint connected to the opening at one end of the liquid cooling pipe; and
a second pipe joint connected to the opening at the other end of the liquid cooling pipe.

14. The busbar assembly according to claim 1, wherein:
the busbar has a single flexible bent part having one end thereof connected to one end of the busbar body; and
the busbar includes two connection end portions adapted to respectively electrically connecting to two busbars, one of the two connection end portions is connected to the other end of the flexible bent part, and the other of the two connection end portions is connected to the other end of the busbar body.

15. An electrical connection assembly, comprising:
two busbar assemblies according to claim 1, with their busbar bodies stacked vertically together; and
an insulation isolation plate clamped between the busbar bodies of the two busbar assemblies, the busbar body has first and second sides opposite in its thickness direction, the first side of the busbar body is attached to the insulation isolation plate, and the liquid cooling tube is located on the second side of the busbar body.

16. The electrical connection assembly according to claim 15, further comprising an installation shell including a top plate and a bottom plate that are opposite in a thickness direction of the busbar body, and a front opening and a rear side plate that are opposite in a width direction of the busbar body, the two busbar bodies and the insulation isolation plate are fixedly installed in the installation shell.

17. The electrical connection assembly according to claim 16, further comprising a fastening assembly fastening the two busbar bodies and the insulation isolation plate to the top plate and bottom plate of the installation shell.

18. The electrical connection assembly according to claim 17, wherein the electrical connection assembly comprises multiple fastening assemblies spaced apart in the length direction of the busbar body, and adjacent two fastening assemblies are respectively located on both sides of the groove.

19. The electrical connection assembly according to claim 17, wherein the fastening assembly comprises:
a first insulation component including an end part clamped between the top plate of the installation shell and one busbar body, and a cylindrical part passing through the two busbar bodies and the insulation isolation plate;
a second insulation component clamped between the bottom plate of the installation shell and the other busbar body;
a nut fixed to the top plate or bottom plate of the installation shell; and
a bolt passing through the top plate and bottom plate of the installation shell, as well as the cylindrical part of the first insulation component, wherein the bolt is threaded with the nut, and the cylindrical part of the first insulation component electrically isolates the bolt from the two busbar bodies.

20. The electrical connection assembly according to claim 16, wherein:
the first pipe joint and the second pipe joint of one busbar assembly pass through the top plate of the installation shell and are fixed to the top plate of the installation shell; and
the first pipe joint and the second pipe joint of the other busbar assembly pass through the bottom plate of the installation shell and are fixed to the bottom plate of the installation shell.

21. The electrical connection assembly according to claim 20, further comprising:
an inlet pipe connected to the first pipe joint of one busbar assembly;
an outlet pipe connected to the first pipe joint of the other busbar assembly; and
a connecting pipe, two ends of which are respectively connected to the second pipe joints of the two busbar assemblies, and interconnect the liquid cooling pipes of the two busbar assemblies.

22. The electrical connection assembly according to claim 21, further comprising two fixed covers respectively fixed to the top plate and bottom plate of the installation shell, the first pipe joints of the two busbar assemblies are respectively accommodated and fixed in the two fixed covers.

23. The electrical connection assembly according to claim 15, wherein the two connection end portions of one busbar of the electrical connection assembly are adapted to electrically connect to two positive connection busbars respectively, and the two connection end portions of the other busbar of the electrical connection assembly are adapted to electrically connect to two negative connection busbars respectively.

24. The electrical connection assembly according to claim 23, wherein:
the connection end portion of the busbar has a vertical connecting plate perpendicular to the length direction of the busbar body, and the vertical connecting plate has a row of teeth suitable for insertion into a row of sockets in the connection busbar; and
the vertical connecting plates at one end of two busbars are spaced apart in the length direction of the busbar body, and the vertical connecting plates at the other end of the two busbars are spaced apart in the length direction of the busbar body.
